(19) United States
(12) Patent Application Publication
(10) Pub. No.: US 2024/0414955 A1
(43) Pub. Date: Dec. 12, 2024

(54) DISPLAY PANEL

(71) Applicants: Yunnan Invensight Optoelectronics Technology Co., Ltd., Yunan (CN); BOE Technology Group Co., Ltd., Beijing (CN)

(72) Inventors: Shengji YANG, Beijing (CN); Xiaochuan Chen, Beijing (CN); Xue Dong, Beijing (CN); Hui Wang, Beijing (CN); Dacheng Zhang, Beijing (CN); Kuanta Huang, Beijing (CN); Pengcheng Lu, Beijing (CN); Zhiqiang Jiao, Beijing (CN)

(21) Appl. No.: 18/808,175

(22) Filed: Aug. 19, 2024

Related U.S. Application Data
(63) Continuation of application No. 18/257,593, filed on Jun. 15, 2023.

(51) Int. Cl. H10K 59/122; H10K 59/12; H10K 71/60

(52) U.S. Cl. CPC H10K 59/122; H10K 59/1201; H10K 71/60

(57) ABSTRACT

A display panel includes a driving backplane, a first electrode layer, a pixel definition layer, a light-emitting layer and a second electrode. The first electrode layer is disposed on one side of the driving backplane and includes a plurality of first electrodes. The pixel definition layer is arranged on the side, same as the first electrode layer, of the driving backplane and being provided with a pixel opening exposing each of the first electrodes. The pixel definition layer is provided with a separation slot formed between adjacent ones of the first electrodes; and a first cut-off slot is provided on a sidewall of the pixel definition layer. The light-emitting layer covers the cut-off layer and the first electrode layer. The second electrode covers the light-emitting layer.

### CROSS REFERENCE TO RELATED APPLICATIONS

This application is a continuation application of U.S. application Ser. No. 18/257,593, which is the US national stage entry of PCT/CN2022/088548, filed on Apr. 2, 2022 which claims priority to International Application number PCT/CN2021/133886, filed on Nov. 29, 2021, entitled “Display Substrate”, the entire disclosures of which are hereby incorporated by reference in its their entirety.

### TECHNICAL FIELD

This disclosure relates to the field of display technologies, and in particular, to a display device, a display panel and a method for manufacturing the display panel.

### BACKGROUND

With the development of display technologies, display panels have been widely used in various electronic devices such as mobile phones to realize image display and touch operation. The OLED (Organic Light-Emitting Diode) display panel is a relatively common one of them. However, the color gamut of existing display panels still needs to be improved.

It should be noted that the information disclosed in the background section above is only used to enhance the understanding of the background of this disclosure, and therefore may include information that does not constitute prior art known to those of ordinary skill in the art.

### SUMMARY

This disclosure provides a display device, a display panel and a method for manufacturing the display panel.

According to an aspect of this disclosure, a display panel is provided and includes:
a driving backplane;
a first electrode layer, disposed on one side of the driving backplane and including a plurality of first electrodes distributed at intervals;
a pixel definition layer, arranged on the side, same as the first electrode layer, of the driving backplane and exposing each of the first electrodes, where the pixel definition layer includes a filling layer and a cut-off layer stacked in a direction away from the driving backplane, the filling layer has a thickness smaller than the first electrode layer and is located outside the first electrodes, the cut-off layer is provided with a separation slot located outside the first electrodes, and a first cut-off slot is provided on a sidewall of the separation slot;
a light-emitting layer, covering the cut-off layer and the first electrode layer; and
a second electrode, covering the light-emitting layer.

In some embodiments of this disclosure, the cut-off layer includes a plurality of insulating layers stacked in the direction away from the driving backplane, the separation slot exposes the filling layer, the first cut-off slot is provided in an insulating layer of the insulating layers, and the insulating layer where the first cut-off slot is located is any insulating layer other than an insulating layer farthest from the driving backplane.

In some embodiments of this disclosure, the insulating layers of the cut-off layer include a first insulating layer, a second insulating layer and a third insulating layer stacked in sequence along the direction away from the driving backplane, and the first cut-off slot is provided in the second insulating layer.

In some embodiments of this disclosure, the sidewall of the separation slot is a slope surface expanding in the direction away from the driving backplane.

In some embodiments of this disclosure, a bottom surface of the first cut-off slot is a slope surface with decreasing depths in the direction away from the driving backplane.

In some embodiments of this disclosure, a slope angle of the bottom surface of the first cut-off slot is larger than a slope angle of the sidewall of the separation slot located on the first insulating layer, and larger than a slope angle of the sidewall of the separation slot located on the third insulating layer.

In some embodiments of this disclosure, a sum of a slope angle of the bottom surface of the first cut-off slot and a slope angle of the sidewall of the separation slot located on the first insulating layer is not greater than 90°.

In some embodiments of this disclosure, a sum of a slope angle of the bottom surface of the first cut-off slot and a slope angle of the sidewall of the separation slot located on the third insulating layer is not greater than 90°.

In some embodiments of this disclosure, an included angle between extending surfaces of two sidewalls of the separation slot is an acute angle.

In some embodiments of this disclosure, the cut-off layer includes a cut-off portion and an extension portion, the cut-off portion is located outside the first electrodes, the extension portion is located on a surface of the first electrodes away from the driving backplane and has a pixel opening exposing the first electrodes, and a sidewall of the pixel opening is a slope surface expanding in the direction away from the driving backplane.

In some embodiments of this disclosure, a sum of a slope angle of the sidewall of the pixel opening and a slope angle of the bottom surface of the first cut-off slot is not greater than 90°.

In some embodiments of this disclosure, the sidewall of at least a part of the pixel opening is provided with a second cut-off slot.

In some embodiments of this disclosure, a maximum depth of the first cut-off slot is greater than a maximum depth of the second cut-off slot.

In some embodiments of this disclosure, a part of the third insulating layer used for forming a sidewall of the first cut-off slot is inclined to the driving backplane at a first inclination angle;
a part of the third insulating layer used for forming a sidewall of the second cut-off slot is inclined to the driving backplane at a second inclination angle; and
the first inclination angle is greater than the second inclination angle.

In some embodiments of this disclosure, a planarization portion is formed in a region of the second electrode corresponding to the first electrodes, and a groove portion is formed in a region of the second electrode corresponding to the separation slot, and a smooth transition is present between the planarization portion and the groove portion.

In some embodiments of this disclosure, a depth of the groove portion is less than a depth of the separation slot.

In some embodiments of this disclosure, a depth of the groove portion is greater than the thickness of the filling layer.

In some embodiments of this disclosure, the filling layer is in contact with a sidewall of the first electrodes.

In some embodiments of this disclosure, the light-emitting layer further includes a plurality of light-emitting sub-layers connected in series, at least one of the light-emitting sub-layers is connected in series with an adjacent one of the light-emitting sub-layers through a charge generation layer, and a part of the charge generation layer corresponding to the first electrodes is discontinuous with a part of the charge generation layer corresponding to the separation slot.

In some embodiments of this disclosure, the filling layer includes a filling insulating layer and a filling conductive layer stacked in the direction away from the driving backplane, the filling insulating layer is in contact with a sidewall of the first electrodes, and the filling conductive layer is spaced apart from the sidewall of the first electrodes.

In some embodiments of this disclosure, the driving backplane includes a pixel area and a peripheral area outside the pixel area, the pixel area is provided with a pixel circuit used for driving light emission of the light-emitting layer, and the peripheral area is provided with a peripheral circuit;
the first electrode layer further includes an adapter ring, an orthographic projection of the adapter ring on the driving backplane is located in the peripheral area and surrounds the pixel area, the adapter ring is connected with the peripheral circuit, the second electrode is connected with the adapter ring, and the adapter ring is provided with a notch;
the filling conductive layer includes a main body and a connecting portion, the main body is located within the adapter ring and is spaced apart from the adapter ring; the connecting portion is connected with the main body, passes out of the adapter ring through the notch, is spaced apart from the adapter ring, and is used for receiving an aging voltage signal.

According to an aspect of this disclosure, a method for manufacturing the display panel as described above includes:
forming the driving backplane;
forming, on a side of the driving backplane, the first electrode layer including the plurality of first electrodes distributed at intervals;
forming, on the side of the driving backplane provided with the first electrode layer, the pixel definition layer exposing each of the first electrodes, where the pixel definition layer includes a filling layer and a cut-off layer stacked in a direction away from the driving backplane, the filling layer has a thickness smaller than the first electrode layer and is located outside the first electrodes;
applying, for a specified period of time, an aging voltage signal to the filling conductive layer;
forming, at the cut-off layer, the separation slot located outside the first electrodes and the first cut-off slot located on a sidewall of the separation slot;
forming the light-emitting layer covering the cut-off layer and the first electrode layer; and
forming the second electrode covering the light-emitting layer.

According to an aspect of this disclosure, a method for manufacturing a display panel is provided and includes:
forming a driving backplane;
forming, on a side of the driving backplane, a first electrode layer including a plurality of first electrodes distributed at intervals;
forming, on the side of the driving backplane formed with the first electrode layer, a pixel definition layer exposing each of the first electrodes, where the pixel definition layer includes a filling layer and a cut-off layer stacked in a direction away from the driving backplane, the filling layer has a thickness smaller than the first electrode layer and is located outside the first electrodes, the cut-off layer is provided with a separation slot located outside the first electrodes, and a first cut-off slot is provided on a sidewall of the separation slot;
forming a light-emitting layer covering the cut-off layer and the first electrode layer; and
forming a second electrode covering the light-emitting layer.

According to an aspect of this disclosure, a display device is provided and includes the display panel according to any one of the above embodiments.

It is to be understood that both the foregoing general description and the following detailed description are exemplary and explanatory only and are not restrictive of this disclosure.

### BRIEF DESCRIPTION OF THE DRAWINGS

The accompanying drawings, which are incorporated in and constitute a part of this specification, illustrate embodiments consistent with the disclosure and together with the description serve to explain the principles of the disclosure. Apparently, the drawings in the following description are only some embodiments of this disclosure, and those skilled in the art can obtain other drawings according to these drawings without creative efforts.

FIG. 1 is a partial cross-sectional view of the display panel according to some embodiments of the of this disclosure.

FIG. 2 is a partial cross-sectional view of the display panel according to some other embodiments of the of this disclosure.

FIG. 3 is a partial cross-sectional view of some film layers in the display panel according to some embodiments of the of this disclosure.

FIG. 4 is a partial cross-sectional view of some film layers in the display panel according to some other embodiments of the of this disclosure.

FIG. 5 is a schematic diagram of a light-emitting unit in the display panel according to some embodiments of the of this disclosure.

FIG. 6 is a partial top view of the display panel according to some embodiments of the of this disclosure.

FIG. 7 is a schematic diagram of a light-emitting unit in the display panel according to some embodiments of the of this disclosure.

FIG. 8 is a partial cross-sectional view of the display panel according to some embodiments of the of this disclosure.

FIG. 9 is a schematic diagram of an adapter ring and a filling conductive layer in the display panel according to some embodiments of the of this disclosure.

### DETAILED DESCRIPTION

Example embodiments will now be described more fully with reference to the accompanying drawings. However, exemplary embodiments may be implemented in many forms and should not be construed as limited to the embodiments set forth herein. Instead, these embodiments are provided so that this disclosure will be thorough and complete, and will fully convey the concept of the exemplary embodiments to those skilled in the art. The same reference numerals in the drawings denote the same or similar structures, and thus their detailed descriptions will be omitted. In addition, the drawings are only schematic representations of this disclosure and, thus, are not necessarily drawn to scale.

The terms “a”, “an”, “the”, “said” and “at least one” are used to indicate the presence of one or more elements/components and the like; the terms “including/comprising” and “have” are used to indicate a nonexclusive meaning and refer to that there may be additional elements/components and the like in addition to the listed elements/components and the like. The terms “first”, “second”, “third” and the like are only used as a marker, not a limit on the number of objects related thereto.

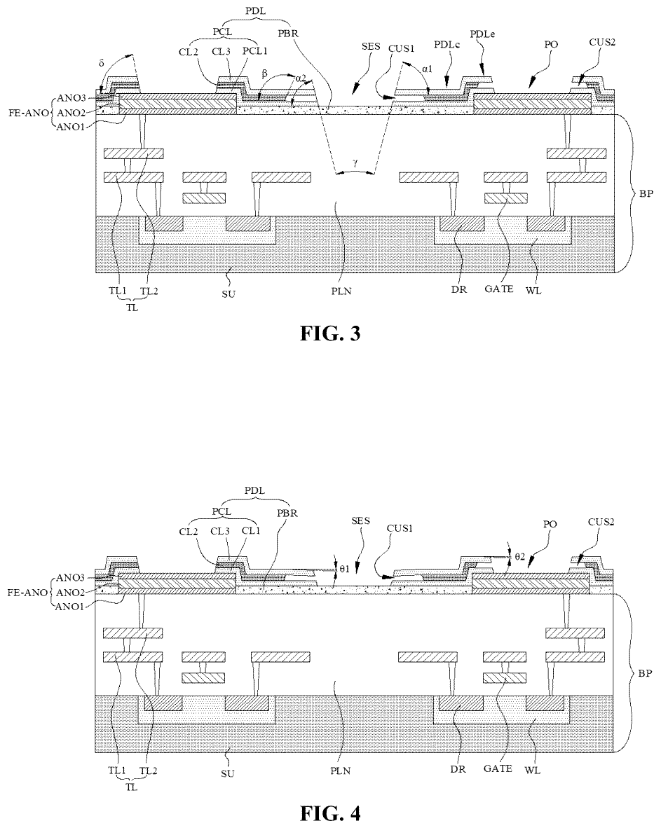

Any “slope (surface)” in this application represents a straight line in the section perpendicular to the driving backplane, and a slope angle of the “slope” (e.g., α1, α2, β, γ and δ in FIG. 3) may be defined as an included angle, among included angles between such straight line or its extended line and a surface where the slope is located, close to the first electrode surrounded by the slope. It should be noted that, taking into account the influence of process errors, the above-mentioned straight line may not be an absolute straight line, but may be a curve extending roughly along a straight line. There may be multiple tangent lines to the curve, each tangent line may form an included angle with the surface where the slope is located, and the slope angle of the curve may be the largest included angle among the included angles, or an average value of the included angles.

In the related art, a silicon-based OLED display panel includes a driving backplane and a light-emitting functional layer, where the light-emitting functional layer is provided on one side of the driving backplane and includes a plurality of light-emitting units. The light-emitting unit may include one or more light-emitting devices connected in series. The light-emitting device may be an organic light-emitting diode, which may include a first electrode (anode), a light-emitting layer, and a second electrode (cathode) stacked in sequence in a direction away from the driving backplane. The light-emitting layer may be driven to emit light by applying electrical signal on the first and second electrodes, while the specific light-emitting principle of the light-emitting device will not be described in detail here.

In addition, the light-emitting layer of each light-emitting device may be directly evaporated through FMM (fine metal mask). The light-emitting layers of respective light-emitting devices are distributed at intervals to emit light independently, thereby realizing color display. However, due to the limitation of FMM manufacturing process, it is difficult to achieve high PPI (pixels per inch). Therefore, color display may also be realized by combining monochromatic light or white light with color film. Specifically, each light-emitting device shares an identical and continuous light-emitting layer, which may emit white light or other monochromatic light. The color film layer is provided with filter units corresponding to the light-emitting units one by one, where a sub-pixel may be formed by one filter unit and a corresponding light-emitting unit, and a pixel is constituted by a plurality of sub-pixels. Different colors of light can pass through different filter units, so that different sub-pixels may emit different colors of light. A single pixel includes multiple sub-pixels with different colors. For example, one pixel may include three sub-pixels whose luminescent colors are red, green and blue, respectively. In this way, color display can be realized by a plurality of pixels.

However, if the light-emitting layer is in a structure of continuous and complete layer, electric leakage may be likely to occur between one light-emitting unit and surrounding light-emitting units, resulting in cross-color. Each light-emitting unit may include a plurality of light-emitting devices connected in series, and respective light-emitting devices of the same light-emitting unit share the first electrode and the second electrode. There are multiple light-emitting sub-layers between the first electrode and the second electrode, and at least two adjacent light-emitting sub-layers may be connected in series through a charge generation layer. Positive charges (holes) may be transferred between two adjacent light-emitting units through the charge generation layer. For example, when the light-emitting units corresponding to the red filter in the color film layer emits light, due to the influence of leakage, the light-emitting units corresponding to the green filter in the color film layer may also emit light, which reduces the purity of light emitted by a single pixel, decreasing the color gamut of the whole display panel.

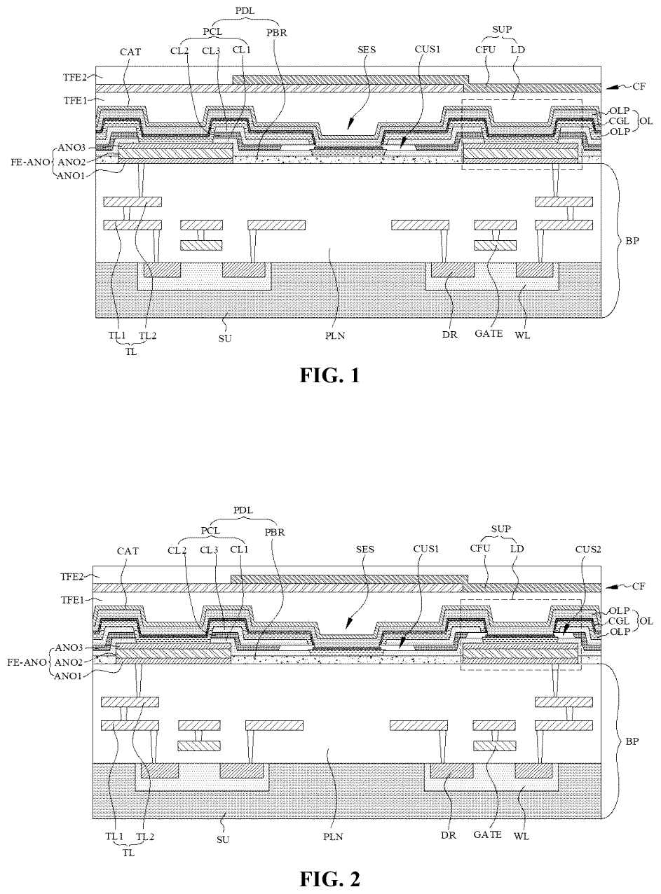

Embodiments of this disclosure provide a display panel. As shown in FIG. 1 and FIG. 2, the display panel may include a driving backplane BP, a first electrode layer FE, a pixel definition layer PDL, a light-emitting layer OL, and a second electrode CAT.

In some embodiments, the first electrode layer FE is disposed on one side of the driving backplane BP and includes a plurality of first electrodes ANO distributed at intervals. The pixel definition layer PDL is arranged on the same side, as the first electrode layer FE, of the driving backplane BP, and exposes each first electrode ANO. The pixel definition layer PDL includes a filling layer PBR and a cut-off layer PCL stacked in a direction away from the driving backplane BP. A thickness of the filling layer PBR is smaller than that of the first electrode layer FE, and is located outside the first electrode ANO. The cut-off layer PCL is provided with a separation slot SES located outside the first electrode ANO, and a first cut-off slot CUS1 is provided on a sidewall of the separation slot SES. The light-emitting layer OL covers the cut-off layer PCL and the first electrode layer FE. The second electrode CAT covers the light-emitting layer OL.

In the display panel according to some embodiments of this disclosure, a light-emitting unit SUP may be constituted by any one of the first electrodes ANO, and the light-emitting layer OL and the second electrode CAT corresponding thereto. The pixel definition layer PDL may separate respective light-emitting units SUP to define the range of each light-emitting unit SUP. Since the sidewall of the separation slot SES is provided with the first cut-off slot CUS1, even if the light-emitting layer OL is recessed into the separation slot SES, it is difficult to be continuously formed in the first cut-off slot CUS1. In other words, at least part of film layers of the light-emitting layer OL can be discontinuous at the first cut-off slot CUS1, thereby reducing the risk of electric leakage between adjacent light-emitting units SUP and alleviating cross-color. In addition, the filling layer PBR may be used to limit the depth of the separation slot SES, and prevent the etching depth, when etching the separation slot SES, from being difficult to be controlled, thereby helping improve the uniformity of different driving backplanes BP.

The structure for realizing the display function of the display panel according to this disclosure will be described in detail below.

As shown in FIG. 1 and FIG. 2, the driving backplane BP may include a pixel area and a peripheral area, where the peripheral area is located outside the pixel area and may be arranged around the pixel area. The driving backplane BP is used to form a driving circuit for driving the light-emitting unit SUP to emit light, and the driving circuit may include a pixel circuit and a peripheral circuit.

In some embodiments, the number of both the pixel circuit and the light-emitting unit SUP may be more than one, and at least a part of the pixel circuits is located within the pixel area. The pixel circuit may be formed in a pixel circuit of 2T1C, 4T1C and the like, as long as it can drive the light-emitting unit SUP to emit light, which will not be specially limited here. The pixel circuits have a same number as the first electrodes ANO, and is connected to the first electrodes ANO in a one-to-one correspondence, so as to respectively control each light-emitting unit SUP to emit light. Herein, nTmC indicates that the pixel circuit includes n transistors (indicated by the letter “T”) and m capacitors (indicated by the letter “C”). In some embodiments, multiple light-emitting units SUP may be driven by a single pixel circuit.

The peripheral circuit is located in the peripheral area and connected with the pixel circuit. The peripheral circuit may include a light emission control circuit, a gate driving circuit, a source driving circuit, etc., and may also include a power supply circuit connected to the second electrode CAT for inputting a power supply signal to the second electrode CAT. The peripheral circuit may enable the light-emitting unit SUP to emit light by inputting signals to the first electrode ANO and the second electrode CAT through the pixel circuits.

In some embodiments of this disclosure, as shown in FIG. 1 and FIG. 2, the driving backplane BP may include a substrate SU, which may be a silicon substrate. The above-mentioned driving circuit may be formed on the silicon substrate through the semiconductor process. For example, both the pixel circuit and the peripheral circuit may include a plurality of transistors, and a well region WL may be formed in the silicon substrate through a doping process, where the well region WL is provided with two doped regions DR distributed at intervals. Take one well region WL as an example, a gate GATE is provided on one side of the driving backplane BP, with an orthographic projection of the gate GATE on the driving backplane BP is located between the two doped regions DR; a transistor may be formed by the well region WL and the gate GATE, with the doped regions DR of the well region WL serving as the first electrode and the second electrode of the transistor, respectively, and the well region WL between the two doped regions DR serving as the channel region of the transistor.

The driving backplane BP may also include at least one trace layer TL and a planarization layer PLN, where the trace layer TL is provided on one side of the substrate SU, the planarization layer PLN covers the trace layer TL, and at least one trace layer TL is connected with each doped region DR.

For example, as shown in FIG. 1 and FIG. 2, the number of trace layers TL is two, which are located within the planarization layer PLN. For example, the trace layers TL include a first trace layer TL1 and a second trace layer TL2, where the first trace layer TL1 is provided on one side of the substrate SU, and a part of the planarization layer PLN is provided between the first trace layer TL1 and the substrate SU. The second trace layer TL2 is provided on one side of the first trace layer TL1 away from the substrate SU, and is separated from the first trace layer TL1 by a part of the planarization layer PLN, and at least a partial region of the second trace layer TL2 is connected with the first trace layer TL1.

Each trace layer TL may be formed by a sputtering process. The planarization layer PLN may be formed of materials including silicon oxide, silicon oxynitride or silicon nitride, and formed layer by layer through multiple deposition and polishing processes. In other words, the planarization layer PLN may be formed by stacking multiple insulating film layers.

As shown in FIG. 1 and FIG. 2, the light-emitting units SUP of the display panel are distributed in array on one side of the driving backplane BP, for example, on a surface of the planarization layer PLN away from the substrate SU. Each light-emitting unit SUP may include a first electrode ANO, a second electrode CAT, and a light-emitting layer OL between the first electrode ANO and the second electrode CAT. The first electrode ANO and the second electrode CAT may both be connected to the trace layer TL. The light-emitting layer OL may be driven to emit light by applying a driving signal to the first electrode ANO and applying a power signal to the second electrode CAT through the driving backplane BP.

In order to realize color display, each light-emitting unit SUP may emit light of the same color and realize color display by cooperating with the color film layer CF located on one side of the second electrode CAT away from the driving backplane BP. Embodiments of this disclosure is described by taking such solution of color display as an example.

In some embodiments of this disclosure, as shown in FIG. 1 and FIG. 2, a plurality of light-emitting units SUP may be formed by the first electrode layer FE, the pixel definition layer PDL, the light-emitting layer OL and the second electrode CAT.

In some embodiments, the first electrode layer FE is disposed on one side of the driving backplane BP, for example, on a surface of the planarization layer PLN away from the substrate SU. The first electrode layer FE may include a plurality of first electrodes ANO distributed at intervals. An orthographic projection of each first electrode ANO on the driving backplane BP is located in the pixel area. The first electrodes ANO are connected to the pixel circuit, with each first electrode ANO being connected to one pixel circuit.

The first electrode layer FE may be a single-layer or multi-layer structure, and its material is not particularly limited here.

For example, as shown in FIG. 1 and FIG. 2, in some embodiments of this disclosure, the first electrode ANO may include a first conductive layer ANO1, a second conductive layer ANO2 and a third conductive layer ANO3 that are stacked in sequence along the direction away from the driving backplane BP. In some embodiments, both the first conductive layer ANO1 and the third conductive layer ANO3 can be made of metal or metal oxide, such as titanium, titanium nitride, and the like, and the materials thereof may be the same or different. The second conductive layer ANO2 may be made of the same material as of a different material from the first conductive layer ANO1 and the third conductive layer ANO3, and has its resistivity lower than that of the first conductive layer ANO1 and the third conductive layer ANO3. For example, the material of the second conductive layer ANO2 may be aluminum.

In some other embodiments of this disclosure, the first electrode ANO may further include a fourth conductive layer, which may be provided on the surface of the third conductive layer away from the driving backplane BP. The fourth conductive layer may be made of a transparent conductive material such as ITO (Indium Tin Oxide) and the like.

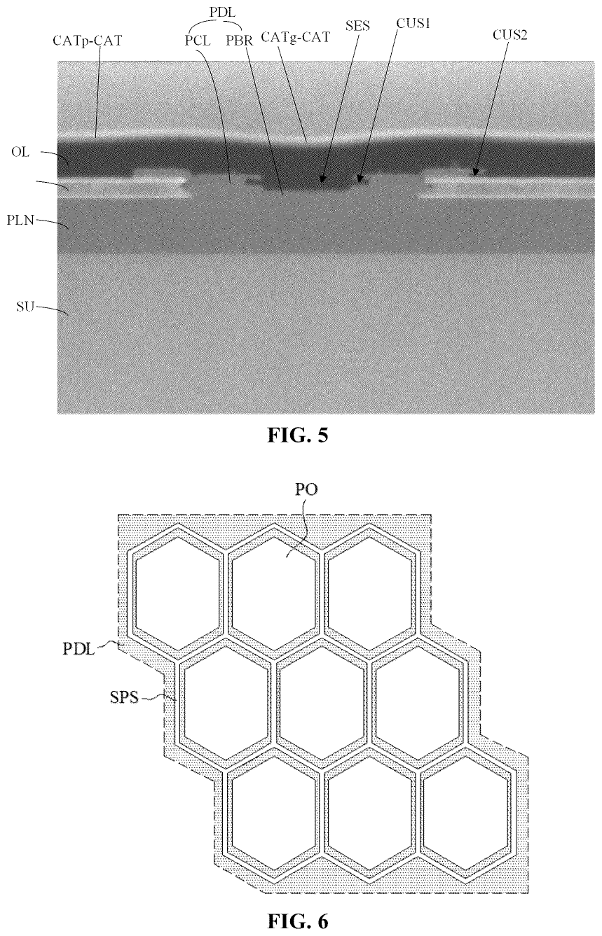

As shown in FIG. 3 and FIG. 4, the pixel definition layer PDL and the first electrode layer FE are provided on the same surface of the driving backplane BP, that is, on the surface of the planarization layer PLN away from the substrate SU. The pixel definition layer PDL exposes each first electrode ANO. Specifically, the pixel definition layer PDL may be provided with a plurality of pixel openings PO exposing each first electrode ANO.

The orthographic projection of any pixel opening PO on the driving backplane BP may be located within a corresponding first electrode ANO exposed thereby. In other words, the pixel opening PO is not larger than the exposed first electrode ANO. For example, the boundary of the pixel opening PO is located inside the boundary of the exposed first electrode ANO, that is, the area of the pixel opening PO is smaller than the area of the exposed first electrode ANO.

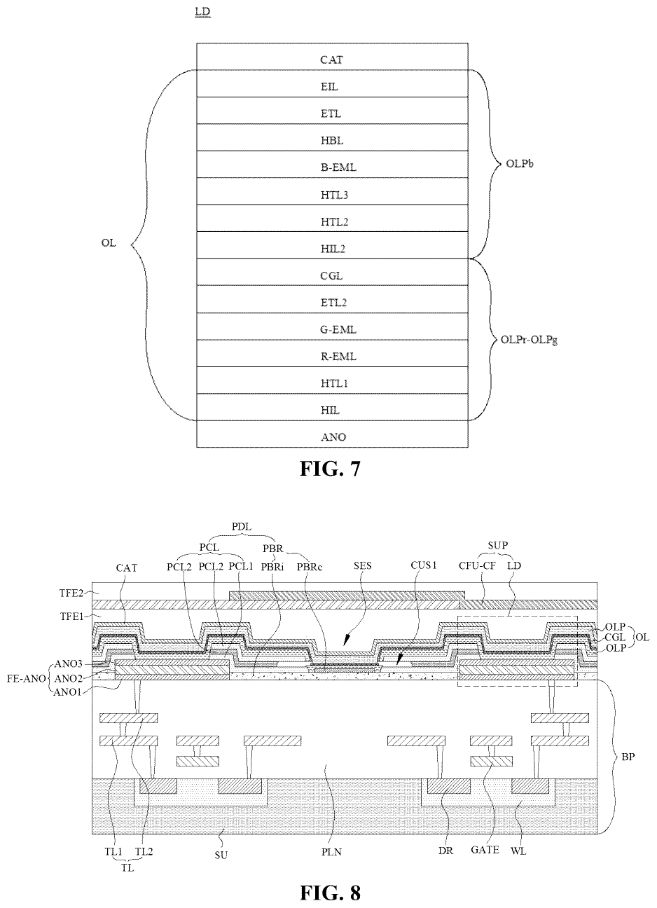

As shown in FIG. 6, the shape of the pixel opening PO may be a polygon such as rectangle, pentagon, hexagon, but not necessarily a regular polygon. The pixel opening PO may also be in other shapes, such as an ellipse and the like, which are not particularly limited here.

As shown in FIG. 1 and FIG. 2, the light-emitting layer OL covers the pixel definition layer PDL and the first electrode ANO, and the area where the light-emitting layer OL and the first electrode ANO are stacked is used to form a light-emitting unit SUP. In other words, respective light-emitting units SUP may share the same light-emitting layer OL, and the parts of the light-emitting layer OL that are stacked on different first electrodes ANO belong to different lighting units SUP. In addition, 20, since respective light-emitting units SUP share the light-emitting layer OL, different light-emitting units SUP can emit light of the same color.

In some embodiments of this disclosure, as shown in FIG. 1, FIG. 2 and FIG. 7, the light-emitting unit SUP may include a plurality of light-emitting devices LD connected in series. Each light-emitting unit SUP includes a first electrode ANO, a second electrode CAT and a plurality of light-emitting sub-layers OLP between the first electrode ANO and the second electrode CAT. Respective light-emitting devices LD of the same light-emitting unit SUP may share the same first electrode ANO and the same second electrode CAT, that is, the same light-emitting unit SUP may have only one first electrode ANO and one second electrode CAT.

For example, as shown in FIG. 1, FIG. 2 and FIG. 7, the light-emitting layer OL may include multiple light-emitting sub-layers OLP connected in series along the direction away from the driving backplane BP, and at least one light-emitting sub-layer OLP is connected in series with an adjacent light-emitting sub-layer OLP through the charge generation layer CGL. When the electric signal is applied to the first electrode ANO and the second electrode CAT, each light-emitting sub-layer OLP can emit light, and different light-emitting sub-layers OLP can be used to emit light of different colors.

Furthermore, as shown in FIG. 7, any light-emitting sub-layer OLP may include a hole injection layer HIL, a hole transport layer HTL, a light-emitting material layer EML, an electron transport layer ETL and an electron injection layer EIL distributed in the direction away from the driving backplane BP. The specific luminescence principle will not be described in detail here.

In some embodiments, the numbers of the hole injection layer HIL, hole transport layer HTL, electron transport layer ETL and electron injection layer EIL are not particularly limited here, and adjacent light-emitting sub-layers OLP may share one or more of the hole injection layer HIL, hole transport layer HTL, electron transport layer ETL and electron injection layer EIL. Moreover, the charge generation layer CGL may be provided between at least two adjacent light-emitting sub-layers OLP, so that the two light-emitting sub-layers OLP are connected in series.

In some embodiments of this disclosure, as shown in FIG. 7, the light-emitting layer OL may include three light-emitting sub-layers OLP with different colors, that is, the first light-emitting sub-layer OLPr that emits red light, the second light-emitting sub-layer OLPg that emits green light, and the third light-emitting sub-layer OLPb that emits blue light. The first light-emitting sub-layer OLPr, the second light-emitting sub-layer OLPg and the third light-emitting sub-layer OLPb may emit light at the same time, so as to emit white light. In some embodiments, the first light-emitting sub-layer OLPr and the second light-emitting sub-layer OLPg share the hole injection layer HIL, the hole transport layer HTL1, the electron transport layer ETL2 and the electron injection layer EIL, and the light-emitting material layer G-EML of the second light-emitting sub-layer OLPg is provided on a surface of the light-emitting material layer R-EML of the first light-emitting sub-layer OLPr away from the driving backplane BP, so that the first light-emitting sub-layer OLPr and the second light-emitting sub-layer OLPg are directly connected in series without using or providing the charge generation layer. The charge generation layer CGL may be provided on the surface of the second light-emitting sub-layer OLPg away from the driving backplane BP. The third light-emitting sub-layer OLPb shares the electron injection layer EIL with the first light-emitting sub-layer OLPr and the second light-emitting sub-layer OLPg, the hole injection layer HIL2 of the third light-emitting sub-layer OLPb is disposed on the surface of the charge generation layer CGL away from the driving backplane BP, and the hole transport layer HTL2 and the hole transport layer HTL3 of the third light-emitting sub-layer OLPb are stacked in sequence on the side of the charge generation layer CGL away from the driving backplane BP, so that the charge generation layer CGL connects the third light-emitting sub-layer OLPb in series with the second light-emitting sub-layer OLPg and the first light-emitting sub-layer OLPr. In addition, a hole filling layer HBL may be provided between the electron transport layer HYL and the light-emitting material layer BEML of the third light-emitting sub-layer OLPb.

The structure of the light-emitting layer OL described above is only an example and does not constitute a limitation to its film layers. It may include only two or more than three light-emitting sub-layers OLP, or include only one light-emitting sub-layer OLP, as long as it can cooperate with the color film layer CF to realize color display.

As shown in FIG. 1, FIG. 2 and FIG. 7, the second electrode CAT covers the light-emitting layer OL, and the orthographic projection of the second electrode CAT on the driving backplane BP may cover the pixel area and extend into the peripheral area. Respective light-emitting units SUP may share the same second electrode CAT. Light emission of the light-emitting layer OL may be controlled by controlling the voltages of the power signal input to the second electrode CAT and the driving signal input to the first electrode ANO.

As shown in FIG. 1 and FIG. 2, the display panel may further include a color film layer CF, which may be disposed on the side of the second electrode CAT away from the driving backplane BP, and includes a plurality of filter units CFU. Respective first electrodes ANO and filter units CFU are arranged opposite to each other one by one in the direction perpendicular to the driving backplane BP. In other words, the orthographic projection of a filter unit CFU on the driving backplane BP at least partially coincides with a first electrode ANO. Each filter CFU includes filter CFUs of at least three colors, for example, a filter unit CFU for passing red light, a filter unit CFU for passing green light, and a filter unit CFU for passing blue light. After the light emitted by each light-emitting unit SUP is filtered by the filter unit CFU, monochromatic light of different colors can be obtained, thereby realizing color display. In some embodiments, a sub-pixel may be constituted by a filter unit CFU and its corresponding light-emitting unit SUP, and the color of light emitted by any sub-pixel is the color of the light transmitted by its filter unit CFU. A pixel may be constituted by a plurality of sub-pixels, and respective sub-pixels in the same pixel emit light of different colors.

The color film layer CF may further include a light-shielding portion for separating the filter units CFU, the light-shielding portion is opaque and shields the area between two light-emitting units SUP. The filter units CFU may be arranged at intervals by using a light-shielding material directly. Alternatively, as shown in FIG. 1 and FIG. 2, in some embodiments of this disclosure, adjacent filter units CFU may be stacked at the area corresponding to two adjacent light-emitting units SUP, with the colors of the light transmitted by them being different, so that the stacked area is opaque.

In addition, in some embodiments of this disclosure, on the basis that the light-emitting layer OL emits white light, in order to improve the brightness of the screen, the color film layer CF may further include a transparent portion. In the direction perpendicular to the substrate, the transparent portion may be provided opposite to the light-emitting unit SUP, so that the color film layer CF can also transmit white light, thereby improving the brightness by the white light.

In order to improve the light extraction efficiency, a light extraction layer may be covered on the side of the second electrode CAT away from the driving backplane BP to improve brightness. Furthermore, the light extraction layer may directly cover the surface of the second electrode CAT away from the driving backplane BP.

In order to facilitate the connection of the second electrode CAT with the driving circuit, in some embodiments of this disclosure, the first electrode layer FE further includes an adapter ring. The orthographic projection of the adapter ring on the driving backplane BP is located in the peripheral area. The adapter ring may be connected with the peripheral circuit, and surround the pixel area. The second electrode CAT may be connected with the adapter ring, so that the second electrode CAT can be connected with the peripheral circuit through the adapter ring, and the driving signal can be applied by the peripheral circuit to the second electrode CAT. The pattern of the adapter ring may be the same as that of the first electrode ANO in the pixel area, so as to improve the uniformity of pattern of the first electrode layer FE.

In some embodiments of this disclosure, as shown in FIG. 1 and FIG. 2, the display panel of this disclosure may further include a first encapsulation layer TFE1, which may be disposed on the side of the second electrode CAT away from the driving backplane BP, located between the color film layer CF and the second electrode CAT, and used to block the erosion of external water and oxygen. The first encapsulation layer TFE1 may be a single-layer or multi-layer structure. For example, the first encapsulation layer TFE1 may include a first encapsulation sub-layer, a second encapsulation sub-layer, and a third encapsulation sub-layer stacked in sequence along the direction away from the driving backplane BP. In some embodiments, materials of the first encapsulation sub-layer and the second encapsulation sub-layer may be inorganic insulating materials such as silicon nitride and silicon oxide, and the second encapsulation sub-layer may be formed by the ALD (Atomic Layer Deposition) process; the material of the third encapsulation sub-layer may be an organic material, and it may be formed by the MLD (Molecular Layer Deposition) process. Alternatively, the first encapsulation layer TFE1 may also adopt other structures, and the structure of the first encapsulation layer TFE1 is not particularly limited here.

In addition, in some embodiments of this disclosure, as shown in FIG. 1 and FIG. 2, the display panel of this disclosure may further include a second encapsulation layer TFE2, which may cover the surface of the color film layer CF away from the driving backplane BP, so as to achieve planarization, to facilitate covering the transparent cover, and to improve the encapsulation effect and further block water and oxygen. The second encapsulation layer may be a single-layer or multi-layer structure, and may include inorganic materials such as silicon nitride and silicon oxide, or organic materials, and the structure of the second encapsulation layer is not particularly limited here.

In addition, the display panel may also include the transparent cover, which may cover the side of the second encapsulation layer TFE2 away from the driving backplane BP. The transparent cover may be a single-layer or multi-layer structure, and its material is not specifically limited.

Based on the above analysis of related art, since respective light-emitting units SUP share the light-emitting layer OL, the carriers (e.g., holes) of a light-emitting unit SUP may move to other light-emitting units SUP, especially to its adjacent light-emitting units SUP, through the charge generation layer CGL. In other words, electric leakage occurs, which may affect the purity of light emission and cause cross-color. Therefore, as shown in FIG. 1 and FIG. 2, the separation slot SES may be provided in the cut-off layer PCLSL, and a first cut-off slot CUS1 may be opened on a side wall of the separation slot SES. Owing to the restriction of the first cut-off slot CUS1, when the light-emitting layer OL is formed, it is difficult to be continuous at the first cut-off slot CUS1, and thus disconnected at the separation slot SES, so as to prevent carriers from moving between the light-emitting units SUP, thereby avoiding cross-color caused by electric leakage. Further, in order to limit the depth of the separation slot SES and prevent it from extending into the driving backplane BP, as well as prevent the depth difference of different display panels from being too large, the etching depth when forming the filling layer PBR may be limited by the filling layer PBR. In other words, the depth of the separation slot SES is limited to the filling layer PBR, which is beneficial to improve the uniformity of the structure of different driving backplanes BP.

The solution directed to the cross-color problem of the display panel according to this disclosure will be described in detail below.

As shown in FIG. 1 and FIG. 2, in order to achieve the above purpose, the pixel definition layer PDL may include at least two layers, i.e., a filling layer PBR and a cut-off layer PCL, and the filling layer PBR may be directly stacked on the driving backplane BP. The filling layer PBR and the first electrode layer FE may be arranged on the same surface of the planarization layer PLN away from the substrate. The filling layer PBR is located outside the first electrode layer FE, and separates the respective first electrodes ANO. In other words, the filling layer PBR may be regarded as a film layer with multiple through holes, with respective first electrodes ANO may be arranged in the through holes in one-to-one correspondence. In addition, in order to provide enough recessed space for the separation slot SES on the cut-off layer PCL, the thickness of the filling layer PBR is smaller than that of the first electrode ANO. For example, for the first electrode ANO including the first conductive layer ANO1, the second conductive layer ANO2 and the third conductive layer ANO3, the thickness of the filling layer PBR may be greater than that of the first conductive layer ANO1, but less than a sum of the thickness of the second conductive layer ANO2 and the thickness of the first conductive layer ANO1. In other words, the surface of the filling layer PBR away from the driving backplane BP is located between the surface of the second conductive layer ANO2 away from the driving backplane BP and the first conductive layer ANO1. In addition, the material of the filling layer PBR may be inorganic insulating materials such as silicon oxide and silicon nitride. Alternatively, other insulating materials may also be used. Moreover, the filling layer PBR may be in contact with the sidewall of the first electrode ANO, that is, the sidewall of the through hole is attached to the sidewall of the first electrode ANO inside the through hole. Since the material of the filling layer PBR is an insulating material, it will not be electrically connected with the first electrode ANO, thereby avoiding short-circuit between the adjacent first electrodes ANO.

As shown in FIG. 1 and FIG. 2, the cut-off layer PCL may be stacked on the surface of the filling layer PBR away from the driving backplane BP, and expose respective first electrodes ANO. A sum of the thickness of the cut-off layer PCL and the filling layer PBR may be greater than the thickness of the first electrode layer FE.

In some embodiments of this disclosure, as shown in FIG. 3, a partial region of the cut-off layer PCL may extend to the surface of the first electrode ANO away from the driving backplane BP, but does not completely cover the first electrode ANO. Correspondingly, the cut-off layer PCL may include a cut-off portion PDLc and an extension portion PDLe. The cut-off portion PDLc may be located outside the first electrode ANO, the extension portion PDLe may be located on the surface of the first electrode ANO away from the driving backplane BP, and there may be an overlapping area between the orthographic projections of the pixel definition layer PDL and the first electrode ANO on the driving backplane BP. The pixel opening PO may be opened in the extension portion PDLe to expose the first electrode ANO. Since the thickness of the first electrode ANO is greater than that of the filling layer PBR, the cut-off layer PCL, when extending from the cut-off portion PDLc to the extension portion PDLe, may need to be raised in height (like climbing a slope). In other words, the surface of the extension portion PDLe away from the first electrode ANO is located at a side, facing away from the driving backplane BP, of the surface of the cut-off portion PDLc away from the driving backplane BP. In addition, in some embodiments, the side wall of the pixel opening PO may be the slope expanding in a direction away from the driving backplane BP.

In some other embodiments of this disclosure, the cut-off layer PCL may not include the extension portion PDLe, but only include the cut-off portion PDLc, and the cut-off portion PDLc may separate the respective first electrodes ANO. In other words, boundaries of the projections of the cut-off portion PDLc and the filling layer PBR on the driving backplane BP may overlap with each other. The pixel opening PO may be a via hole penetrating the cut-off portion PDLc and the filling layer PBR, and there is no overlapping region between the orthographic projections of the pixel definition layer PDL and the first electrode ANO on the driving backplane BP.

As shown in FIG. 1 and FIG. 2, the cut-off layer PCL is provided with the separation slot SES, and the separation slot SES is located outside the first electrode ANO, which may be an annular slot surrounding the first electrode ANO, with each first electrode ANO may be surrounded by a separation slot SES. Separation slots SES surrounding two adjacent first electrodes ANO may share a partial area, so that there may be only one separation slot SES between two adjacent first electrodes ANO, with one side wall of the separation slot SES surrounding outside an electrode, and the two side walls of the separation slot SES. Alternatively, separation slots SES may also be opened independently surrounding two adjacent first electrodes ANO without any shared part. In addition, the side wall of the separation slot SES may be a slope expanding in the direction away from the driving backplane BP, that is, the distance between two side walls of the separation slot SES increases gradually along the direction away from the driving backplane BP, and the slope angle of the side walls of the separation slot SES is less than or equal to 90°.

As shown in FIG. 1 and FIG. 2, the side wall of the separation slot SES is provided with a first cut-off slot CUS1, and the first cut-off slot CUS1 may recess from the side wall of the separation slot SES to the first electrode ANO surrounded by the separation slot SES, with the recessing direction being its depth direction. The depth of the first cut-off slot CUS1 may be smaller than the distance between the side wall where it is located and the first electrode ANO, that is to say, the first cut-off slot CUS1 does not penetrate the cut-off layer PCL in its depth direction.

As shown in FIG. 1 and FIG. 2, the first cut-off slot CUS1 may extend along the extending direction of the separation slot SES, thereby forming an annular slot on the sidewall of the separation slot SES. The light-emitting layer OL covers the cut-off layer PCL and the first electrode layer FE, and is recessed into the separation slot SES. However, due to the existence of the first cut-off slot CUS1, the charge generation layer CGL or other film layers of the light-emitting layer OL may be difficult to be formed within the first cut-off slot CUS1 and, instead, tend to be disconnected on the side wall of the separation slot SES. For example, a part of the charge generation layer CGL corresponding to the first electrode ANO is disconnected from a part thereof corresponding to the separation slot SES, thereby avoiding cross-color between adjacent light-emitting units SUP.

In order to ensure the cut-off effect, first cut-off slots CUS1 may be provided on both sides of the separation slot SES, and one or more first cut-off slots CUS1 may be opened on a single side wall thereof. If a plurality of first cut-off slots CUS1 are provided on one side wall, respective first cut-off slots CUS1 may be distributed at intervals along the direction away from the driving backplane BP.

The specific manner of forming the first cut-off slot CUS1 will be described in detail below.

As shown in FIG. 1 and FIG. 2, in some embodiments of this disclosure, the cut-off layer PCL includes multiple insulating layers stacked in the direction away from the driving backplane BP. The material of each insulating layer may be insulating inorganic materials such as silicon oxide, silicon nitride, and the like, there is no special limitation here, and the materials of different insulating layers are the same or different. The separation slot SES may expose the filling layer PBR, that is, the separation slot SES penetrates respective insulating layers. The first cut-off slot CUS1 may be opened on an insulating layer, and the insulating layer where it is located is any insulating layer except the insulating layer farthest from the driving backplane BP. For example, the number of insulating layers of the cut-off layer PCL may be three, that is, the first insulating layer CL1, the second insulating layer CL2 and the third insulating layer CL3 sequentially stacked along the direction away from the driving backplane BP, where the first cut-off slot CUS1 may be opened in the second insulating layer CL2. As shown in FIG. 3, the separation slot SES penetrates through the first insulating layer CL1 and the third insulating layer CL3, the sidewall of a part of the separation slot SES located in the first insulating layer CL1 may be a slope surface expanding in the direction away from the driving backplane BP, and the side wall of a part of the separation slot SES located in the third insulating layer CL3 may be a slope surface expanding in the direction away from the driving backplane BP, with the slope angles of above two slope surfaces, α1 and α2, being neither greater than 90° and, optionally, being the same.

The material of the insulating layer, where the first cut-off slot CUS1 is to be formed, may be different from that of other insulating layers. When the first cut-off slot CUS1 is formed, the separation slot SES and the first cut-off slot CUS1 may be formed based on different degrees of etching when different materials are etched by the etching process. Alternatively, other processed may also be adopted, as long as the separation slot SES and the first cut-off slot CUS1 can be formed.

As shown in FIG. 3, two side walls of the first cut-off slot CUS1 may be distributed along the direction away from the driving backplane BP, there is a bottom surface between the two side walls, and the bottom surface surrounds outside the first electrode ANO. The bottom surface may be a slope surface along which the depth of the first cut-off slot CUS1 is reduced in the direction away from the driving backplane BP. In other words, the bottom surface of the first cut-off slot CUS1 surrounding the first electrode ANO is an annular surface expanding in the direction close to the driving backplane BP, that is, the slope angle β of the bottom surface of the first cut-off slot CUS1 is greater than 90°. Alternatively, the bottom surface of the first cut-off slot CUS1 may also be perpendicular to the driving backplane BP.

As shown in FIG. 3, the slope angle β of the bottom surface of the first cut-off slot CUS1 is greater than the slope angle α1 of a side wall of the separation slot SES located in the first insulating layer CL1, and greater than the slope angle α2 of a side wall of the separation slot SES located in the third insulating layer CL3. In addition, a sum of the slope angle β of the bottom surface of the first cut-off slot CUS1 and the slope angle α1 of the sidewall of the separation slot SES located in the first insulating layer CL1 is not greater than 90°, for example, it may be 50°, 60° or the like. Moreover, a sum of the slope angle β of the bottom surface of the first cut-off slot CUS1 and the slope angle α2 of the sidewall of the separation slot SES located in the third insulating layer CL3 is not greater than 90°. In some other embodiments of this disclosure, slope angles of the two slope surfaces may be different. Furthermore, as shown in FIG. 3, a sum of a slope angle δ of the sidewall of the pixel opening PO and the slope angle β of the bottom surface of the first cut-off slot CUS1 may be not less than 90°.

In some embodiments of this disclosure, one side wall of the first cut-off slot CUS1 is located in the first insulating layer CL1, while the other side wall thereof is located in the third insulating layer CL3, and an included angle γ between extension surfaces of the two side walls of the separation slot SES is an acute angle, so that the sidewall located in the third insulating layer CL3 is shorter than the sidewall located in the first insulating layer CL1. In other words, a suspended part of the third insulating layer CL3 corresponding to the first cut-off slot CUS1 is shorter than a part of the first insulating layer CL1 corresponding to the first cut-off slot CUS1. In addition to cutting off the light-emitting layer OL, a risk that the third insulating layer CL3 is broken due to the first cut-off slot CUS1 can be reduced.

In some embodiments of this disclosure, as shown in FIG. 2 and FIG. 3, for the pixel definition layer PDL having the extension portion PDLe, a second cut-off slot CUS2 may be provided on the side wall of at least a part of the pixel openings PO. As the pixel opening PO is located in the extension portion PDLe, the second cut-off slot CUS2 is actually opened on the extension portion PDLe. Accordingly, the charge generation layer CGL may be disconnected by the second cut-off slot CUS2, thereby further preventing cross-color. For the specific implementation of the second cut-off slot CUS2, that of the first cut-off slot CUS1 may be referred. For example, the second cut-off slot CUS2 is opened in the second insulating layer CL2, so that the third insulating layer CL3 is suspended at the second cut-off slot CUS2. Moreover, in order to prevent the extension portion PDLe from causing a large shield to the first electrode ANO, an area of the extension portion PDLe is relatively small. Correspondingly, it may be necessary to limit the depth of the second cut-off slot CUS2, so that the maximum depth of the first cut-off slot CUS1 is greater than the maximum depth of the second cut-off slot CUS2. In addition to ensuring that the second cut-off slot CUS2 can cut off at least part of the film layers of the light-emitting layer OL, the depth thereof can be prevented from being sufficiently large to cut off the extension PDLe, which is beneficial to maintain the stability of the structure.

Further, the second cut-off slot CUS2 may be formed on the extension portion PDLe of each first electrode ANO; and the second cut-off slot CUS2 may also be formed on the extension portion PDLe of the first electrode ANO of a specific light-emitting unit SUP. For example, in the color film layer CF, the range of the blue filter CFU is larger than the range of the red and green filter CFU, that is, the orthographic projection of the blue filter CFU on the driving backplane BP has a greater area than the orthographic projection of the red and green filter CFU on the driving backplane BP. So the second cut-off slot CUS2 may be provided on the sidewall of the pixel opening PO of the blue sub-pixel, rather than being provided in the pixel opening PO of the red and green sub-pixels.

In some embodiments of this disclosure, as shown in FIG. 4, for the first cut-off slot CUS1 and the second cut-off slot CUS2 formed on the second insulating layer CL2, a part of the third insulating layer CL3 used to form the sidewall of the first cut-off slot CUS1 is inclined to the driving backplane BP, and the inclination angle is a first inclination angle θ1. In other words, the two sidewalls of the first cut-off slot CUS1 may not be parallel to each other. A part of the third insulating layer CL3 used to form the sidewall of the second cut-off slot CUS2 is inclined to the driving backplane BP, and the inclination angle is the second inclination angle θ2. In other words, the two side walls of the second cut-off slot CUS2 may not be parallel to each other. In some embodiments, the first inclination angle θ1 may be greater than the second inclination angle θ2, that is, compared with the area of the third insulating layer CL3 in the second cut-off slot CUS2, the third insulating layer CL3 is more inclined in the area of the first cut-off slot CUS1.

As shown in FIG. 5, based on the topography of the above-mentioned pixel definition layer PDL and light-emitting layer OL, a planarization portion CATp may be formed in a region of the second electrode CAT corresponding to the first electrode ANO, and a groove portion may be formed in a region thereof corresponding to the separation slot SES. A smooth transition may be present at the connection between the groove portion CATg and the planarization portion CATp, so as to avoid sharp corners of the second electrode CAT. The separation slot SES is filled by the light-emitting layer OL, such that the depth of the groove portion CATg of the second electrode CAT is smaller than that of the separation slot SES. In addition, the depth of the groove portion CATg may be greater than the thickness of the filling layer PBR.

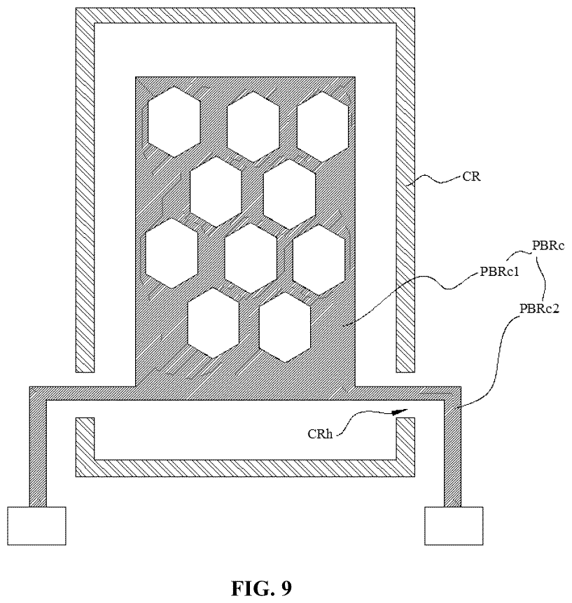

In addition, in some embodiments of this disclosure, as shown in FIG. 8 and FIG. 9, for the light-emitting layer OL provided in the entire layer, that is, in the case where respective light-emitting units SUP share an entire light-emitting layer OL, aging treatment may be performed on the light-emitting layer OL between the light-emitting units SUP, so as to increase an impedance of the light-emitting layer OL in the aging area, thereby reducing the ability of the light-emitting layer OL to conduct laterally, and weakening the leakage between adjacent light-emitting units SUP.

For example, the filling layer PBR may include a filling insulating layer PBRi and a filling conductive layer PBRc stacked in the direction away from the driving backplane.

In some embodiments, the material of the filling insulating layer PBR may be insulating materials such as silicon nitride and silicon oxide, and the filling insulating layer PBRi is in contact with the sidewall of the first electrode ANO. The material of the filling conductive layer PBRc may be metal or other conductive materials, and is spaced apart from the sidewall of the first electrode ANO, so as to be insulated from the first electrode ANO. In this case, the bottom of the separation slot SES may not be flat, it may include a surface, that is not covered by the filling conductive layer PBRc, of the filling insulating layer PBR away from the driving backplane BP, and may also include a surface of the filling conductive layer PBRc away from the driving backplane BP. The first cut-off slot CUS1 is located on the side of the filling conductive layer PBRc away from the driving backplane BP, that is, above the filling conductive layer PBRc. The cut-off layer PCL may cover the filling conductive layer PBRc, or may also be located outside the filling conductive layer PBRc, as long as it does not affect the formation of the first cut-off slot CUS1.

The first electrode layer FE may also include an adapter ring CR, the orthographic projection of the adapter ring CR on the driving backplane BP is located in the peripheral area and surrounds the pixel area. The adapter ring CR is connected to the peripheral circuit, and the second electrode CAT is connected to the adapter ring CR. As to the adapter ring CR, the forgoing embodiments may be referred to, which will not be repeated here. The adapter ring CR is provided with a notch CRh for disconnecting it.

The filling conductive layer PBRc may include a main body PBRc1 and a connecting portion PBRc2. The main body PBRc is located within the adapter ring CR and spaced apart from the adapter ring CR, so as to be insulated from the adapter ring CR. The connecting portion PBRc2 is connected with the main body PBRc1, passes out of the adapter ring CR through the notch CRh, is spaced apart from the adapter ring CR. In other words, the connecting portion PBRc2 does not contact the notch CRh and, thus, is insulated from the adapter ring CR. The main body PBRc1 and the connecting portion PBRc2 may be integrally formed and may be formed at the same time.

The connection portion PBRc2 may be connected with the peripheral circuit for receiving the aging voltage signal, so as to cooperate with the second electrode CAT to apply the aging voltage to the light-emitting layer OL, so that the light-emitting layer OL is aged in the area corresponding to the main body PBRc1, with the impedance being increased. The aging voltage may depend on the material and thickness of the light-emitting layer OL, for example, may be greater than 8v, 15v, 20v, 30v, and the like, which is not particularly limited here, as long as the light-emitting material OL can be aged. In addition, the duration of the aging voltage may also be controlled to a specified duration, that is, the duration of the aging voltage signal is a specified duration. The specified duration may not be greater than 10 seconds and, alternatively, may be longer, as long as the light-emitting material OL can be aged.

Embodiments of this disclosure further provide a method for manufacturing the display panel. The display panel may be the display panel in any of the above embodiments, and its structure will not be described in detail here. The manufacturing method may include steps S110-S140.

In step S110, a driving backplane is formed.

In step S120, a first electrode layer, including a plurality of first electrodes distributed at intervals, is formed on one side of the driving backplane.

In step S130, a pixel definition layer, exposing each first electrode, is formed on the side of the driving backplane on which the first electrode layer is formed, where the pixel definition layer includes a filling layer and a cut-off layer stacked in a direction away from the driving backplane, the filling layer has a thickness smaller than the first electrode layer and is located outside the first electrodes; the cut-off layer is provided with a separation slot located outside the first electrodes, and the side wall of the separation slot is provided with a first cut-off slot.

In step S140, a light-emitting layer covering the cut-off layer and the first electrode layer is formed.

In step S150, a second electrode covering the light-emitting layer is formed.

Based on the above-mentioned display panel provided with the filling insulating layer PBRi and filling conductive layer PBRc, in some embodiments of this disclosure, the manufacturing method may include steps S110-S170.

In step S110, a driving backplane is formed.

In step S120, a first electrode layer, including a plurality of first electrodes distributed at intervals, is formed on one side of the driving backplane.

In step S130, a pixel definition layer, exposing each first electrode, is formed on the side of the driving backplane on which the first electrode layer is formed, where the pixel definition layer includes a filling layer and a cut-off layer stacked in a direction away from the driving backplane, the filling layer has a thickness smaller than the first electrode layer and is located outside the first electrodes.

In step S140, an aging voltage signal is applied to the filling conductive layer for a specified period of time.

In step S150, a separation slot located outside the first electrodes and a first cut-off slot located on the side wall of the separation slot are formed in the cut-off layer.

In step S160, a light-emitting layer covering the cut-off layer and the first electrode layer is formed.

In step S170, a second electrode covering the light-emitting layer is formed.

Since details of the structure involved in each step of the above-mentioned manufacturing method have been described in detail in the forgoing embodiments of the display panel, the details and beneficial effects thereof will not be described in detail here.

It should be noted that although various steps of the manufacturing method in this disclosure are described in a specific order in the drawings, this does not require or imply that these steps must be performed in this specific order, or that all shown steps must be performed to achieve the desired result. Additionally or alternatively, certain steps may be omitted, multiple steps may be combined into one step for implementation, and/or one step may be decomposed into multiple steps for implementation.

Embodiments of this disclosure further provide a display device, which may include the display panel in any of the above embodiments. The specific structure and beneficial effects of the display panel have been described in detail in the forgoing embodiments of the display panel, and will not be described in detail here. The display device according to this disclosure may be used in electronic devices with image display functions, such as watches, bracelets, mobile phones, and tablet computers, and will not be elaborated here.

Other embodiments of this disclosure will be readily apparent to those skilled in the art from consideration of the specification and practice of the application disclosed herein. This application is intended to cover any modification, use or adaptation of this disclosure, and these modifications, uses or adaptations follow the general principles of this disclosure and include common knowledge or conventional technical means in the technical field not disclosed in this disclosure. The specification and embodiments are to be considered exemplary only, with the actual scope and spirit of the disclosure being indicated by the appended claims.

What is claimed is:

1. A display panel, comprising:
a driving backplane;
a first electrode layer, disposed on one side of the driving backplane and comprising a plurality of first electrodes distributed at intervals;
a pixel definition layer, arranged on the side, same as the first electrode layer, of the driving backplane and being provided with a pixel opening exposing each of the first electrodes, wherein the pixel definition layer is provided with a separation slot formed between adjacent ones of the first electrodes; a first cut-off slot is provided on a sidewall of the pixel definition layer; the pixel definition layer comprises a cut-off layer consisting of a plurality of insulating layers stacked in a direction away from the driving backplane, and the first cut-off slot is provided in one of the insulating layers;
a light-emitting layer, covering the cut-off layer and the first electrode layer; and
a second electrode, covering the light-emitting layer; wherein a planarization portion is formed in a region of the second electrode corresponding to the pixel opening; a groove portion is formed in a region of the second electrode corresponding to the separation slot; and, in a direction perpendicular to the driving backplane, a distance between the groove portion and the planarization portion is smaller than a depth of the separation slot.

2. The display panel according to claim 1, wherein the pixel opening is located on the cut-off layer, and the first cut-off slot is provided on a sidewall of the pixel opening.

3. The display panel according to claim 2, wherein the insulating layers of the cut-off layer comprise a first insulating layer, a second insulating layer and a third insulating layer stacked in sequence along the direction away from the driving backplane, and the first cut-off slot is provided in the second insulating layer.

4. The display panel according to claim 3, wherein a sidewall of the separation slot is a slope surface expanding in the direction away from the driving backplane.

5. The display panel according to claim 3, wherein the separation slot is located outside the first electrodes, and both a slope angle of a sidewall of the separation slot located on the first insulating layer and a slope angle of a sidewall of the separation slot located on the third insulating layer are acute angles.

6. The display panel according to claim 3, wherein a suspended part of the third insulating layer corresponding to the first cut-off slot is shorter than a part of the first insulating layer corresponding to the first cut-off slot.

7. The display panel according to claim 4, wherein the separation slot is located outside the first electrodes, and a bottom surface of the first cut-off slot is a slope surface with decreasing depths in the direction away from the driving backplane.

8. The display panel according to claim 4, wherein the separation slot is located outside the first electrodes, and a slope angle of a bottom surface of the first cut-off slot is larger than 90°.

9. The display panel according to claim 7, wherein a slope angle of the bottom surface of the first cut-off slot is larger than a slope angle of the sidewall of the separation slot located on the first insulating layer, and larger than a slope angle of the sidewall of the separation slot located on the third insulating layer.

10. The display panel according to claim 7, wherein a sum of a slope angle of the bottom surface of the first cut-off slot and a slope angle of the sidewall of the separation slot located on the first insulating layer is not greater than 90°.

11. The display panel according to claim 7, wherein a sum of a slope angle of the bottom surface of the first cut-off slot and a slope angle of the sidewall of the separation slot located on the third insulating layer is not greater than 90°.

12. The display panel according to claim 4, wherein an included angle between extending surfaces of two sidewalls of the separation slot is an acute angle.

13. The display panel according to claim 7, wherein the cut-off layer comprises a cut-off portion and an extension portion, the cut-off portion is located outside the first electrodes, the extension portion is located on a surface of the first electrodes away from the driving backplane and has a pixel opening exposing the first electrodes, and a sidewall of the pixel opening is a slope surface expanding in the direction away from the driving backplane.

14. The display panel according to claim 13, wherein a sum of a slope angle of the sidewall of the pixel opening and a slope angle of the bottom surface of the first cut-off slot is not greater than 90°.

15. The display panel according to claim 13, wherein the sidewall of at least a part of the pixel opening is provided with a second cut-off slot.

16. The display panel according to claim 15, wherein a maximum depth of the first cut-off slot is greater than a maximum depth of the second cut-off slot.

17. The display panel according to claim 16, wherein a part of the third insulating layer used for forming a sidewall of the first cut-off slot is inclined to the driving backplane at a first inclination angle;
a part of the third insulating layer used for forming a sidewall of the second cut-off slot is inclined to the driving backplane at a second inclination angle; and
the first inclination angle is greater than the second inclination angle.

18. The display panel of claim 1, wherein the pixel definition layer further comprises a filling layer, the filling layer and the cut-off layer are stacked in the direction away from the driving backplane, the filling layer has a thickness smaller than the first electrode layer and is located outside the first electrodes; the separation slot is located outside the first electrodes and exposes the filling layer; and a depth of the groove portion is greater than the thickness of the filling layer.

19. The display panel according to claim 18, wherein the filling layer is in contact with a sidewall of the first electrodes.

20. The display panel according to claim 18, wherein the light-emitting layer further comprises a plurality of light-emitting sub-layers connected in series, at least one of the light-emitting sub-layers is connected in series with an adjacent one of the light-emitting sub-layers through a charge generation layer, and a part of the charge generation layer corresponding to the first electrodes is discontinuous with a part of the charge generation layer corresponding to the separation slot.
